(19) United States
(12) Patent Application Publication
(10) Pub. No.: US 2020/0303381 A1
(43) Pub. Date: Sep. 24, 2020

(54) NONVOLATILE STATIC RANDOM ACCESS MEMORY (SRAM) DEVICES

(71) Applicant: Intel Corporation, Santa Clara, CA (US)

(72) Inventors: Elijah KARPOV, Portland, OR (US); Brian DOYLE, Portland, OR (US); Abhishek SHARMA, Hillsboro, OR (US); Prashant MAJHI, San Jose, CA (US); Pulkit JAIN, Hillsboro, OR (US)

(21) Appl. No.: 16/357,221

(22) Filed: Mar. 18, 2019

(51) Int. Cl. H01L 27/11; H01L 49/02; H05K 1/18

(52) U.S. Cl. CPC H01L 27/1104; H05K 2201/10159; H05K 1/18; H01L 28/55

(57) ABSTRACT

Embodiments herein describe techniques for a semiconductor device including a SRAM device having multiple SRAM memory cells, and a capacitor coupled to the SRAM device. The capacitor includes a first plate, a second plate, and a capacitor dielectric layer between the first plate and the second plate. The capacitor is to supply power to the multiple SRAM memory cells of the SRAM device in parallel for a period of time. Other embodiments may be described and/or claimed.

### FIELD

Embodiments of the present disclosure generally relate to the field of computing devices, and more particularly, to nonvolatile static random access memory (SRAM) devices.

### BACKGROUND

The memory system is an important component of modern computers and communication devices. Volatile and high speed memory like static random access memory (static RAM or SRAM) may be used for cache and main memory, while magnetic disks may be used for high-end data storage. In addition, persistent and low speed flash memory may be used for storage with low capacity and/or low energy consumption in embedded or mobile devices. SRAM devices use power to maintain the data stored therein. Data stored in a SRAM device maybe lost when power goes off, e.g., external battery fails or removed.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 schematically illustrates a semiconductor device including a capacitor to supply power in parallel to multiple static random access memory (SRAM) memory cells of a SRAM device, in accordance with some embodiments.

FIGS. 2(a)-2(d) schematically illustrate various structures of a capacitor that can supply power in parallel to multiple SRAM memory cells of a SRAM device, in accordance with some embodiments.

FIGS. 3(a)-3(c) schematically illustrate semiconductor devices including a capacitor to supply power in parallel to multiple SRAM memory cells of a SRAM device, in accordance with some embodiments.

FIG. 4 schematically illustrates a process for forming a semiconductor device including a capacitor to supply power in parallel to multiple SRAM memory cells of a SRAM device, in accordance with some embodiments.

FIG. 5 schematically illustrates an interposer implementing one or more embodiments of the disclosure, in accordance with some embodiments.

FIG. 6 schematically illustrates a computing device built in accordance with an embodiment of the disclosure, in accordance with some embodiments.

### DETAILED DESCRIPTION

High speed memory devices like static random access memory (static RAM or SRAM) device may be used for cache and main memory. However, SRAM devices are volatile. SRAM devices need power to maintain the data stored therein. Data stored in a SRAM device maybe lost when power goes off, e.g., external battery fails or removed. Currently, battery may be used to provide power for standalone SRAM devices. However, an external battery cannot be utilized for SRAM used inside a processor.

Embodiments herein may present techniques and apparatus to provide power to a SRAM device for a period of time, which may be referred to as a semi-nonvolatile memory device. In detail, a capacitor is coupled to a SRAM device to supply power in parallel to multiple SRAM memory cells of the SRAM device for a period of time. Embodiments herein may prevent loss of data stored in a SRAM device when power goes off. In addition, semi-nonvolatile SRAM devices can reduce energy consumption when data moves in and out of SRAM.

Embodiments herein may provide a semiconductor device including a SRAM device having multiple SRAM memory cells, and a capacitor coupled to the SRAM device. The capacitor includes a first plate, a second plate, and a capacitor dielectric layer between the first plate and the second plate. The capacitor is to supply power to the multiple SRAM memory cells of the SRAM device in parallel for a period of time.

Embodiments herein may present a method for forming a semiconductor device. The method includes forming a SRAM device including multiple SRAM memory cells. The method also includes forming a capacitor coupled to the multiple SRAM memory cells of the SRAM device in parallel to supply power to the multiple SRAM memory cells of the SRAM device for a period of time. The capacitor includes a first plate, a second plate, and a capacitor dielectric layer between the first plate and the second plate.

Embodiments herein may present a computing device including a print circuit board (PCB), and a semiconductor device coupled to the PCB. The semiconductor device includes a SRAM device including multiple SRAM memory cells, and a capacitor coupled to the SRAM device. The capacitor includes a first plate, a second plate, and a capacitor dielectric layer between the first plate and the second plate. The capacitor is to supply power in parallel to the multiple SRAM memory cells of the SRAM device for a period of time.

In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure. However, the order of description should not be construed to imply that these operations are necessarily order dependent. In particular, these operations may not be performed in the order of presentation. For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

As used herein, the term “circuitry” may refer to, be part of, or include an Application Specific Integrated Circuit (ASIC), an electronic circuit, a processor (shared, dedicated, or group), and/or memory (shared, dedicated, or group) that execute one or more software or firmware programs, a combinational logic circuit, and/or other suitable hardware components that provide the described functionality. Circuitry may include one or more transistors. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

Implementations of the disclosure may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present disclosure.

A plurality of transistors, such as metal-oxide-semiconductor field-effect transistors (MOSFET or simply MOS transistors), may be fabricated on the substrate. In various implementations of the disclosure, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the disclosure may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type work function metal or N-type work function metal, depending on whether the transistor is to be a PMOS or an NMOS transistor. In some implementations, the gate electrode layer may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a work function that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a work function that is between about 3.9 eV and about 4.2 eV.

In some implementations, when viewed as a cross-section of the transistor along the source-channel-drain direction, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the disclosure, the gate electrode may consist of a combination of U-shaped structures and planar, non-U-shaped structures. For example, the gate electrode may consist of one or more U-shaped metal layers formed atop one or more planar, non-U-shaped layers.

In some implementations of the disclosure, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process operations. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

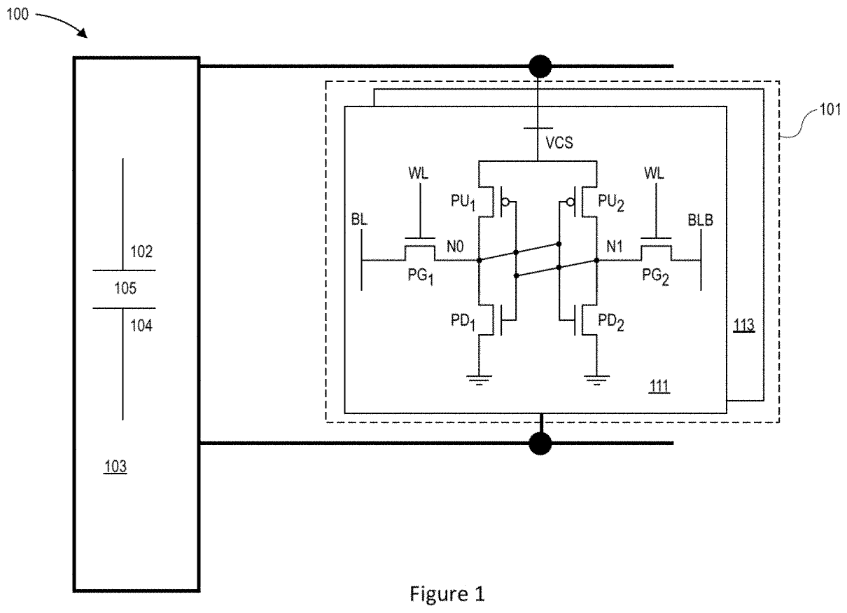

FIG. 1 schematically illustrates a semiconductor device 100 including a capacitor 103 to supply power in parallel to multiple SRAM memory cells of a SRAM device 101, in accordance with some embodiments.

In embodiments, the semiconductor device 100 includes the SRAM device 101 coupled to the capacitor 103. The SRAM device 101 includes multiple SRAM memory cells, e.g., a SRAM memory cell 111, and a SRAM memory cell 113, and the capacitor 103 is coupled to the SRAM memory cell 111, and the SRAM memory cell 113 in parallel. There may be many more SRAM memory cells within the SRAM device 101. For example, the SRAM device 101 may have a size in a range of about 4 kb to 32 Mb. The SRAM memory cell 111, and the SRAM memory cell 113 may be any of the configurations for a SRAM memory cell, e.g., a SRAM memory cell with 4 transistors, a SRAM memory cell with 6 transistors, or a SRAM memory cell with 8 transistors. In some embodiments, the SRAM device 101 may be located in a cache of the processor.

In embodiments, the capacitor 103 is to supply power in parallel to the multiple SRAM memory cells, e.g., the SRAM memory cell 111, and the SRAM memory cell 113, of the SRAM device 101 for a period of time. On other words, the single one capacitor 103 supplies power to multiple SRAM memory cells at the same time. Such a design is different from a design where each SRAM memory cell can have power supplied by an individual capacitor. When each SRAM memory cell can have power supplied by an individual capacitor, it is harder and more routing for the power supply to the multiple capacitors to supply power to the multiple SRAM memory cells. Embodiments herein has one capacitor to supply power in parallel to the multiple SRAM memory cells, hence reducing the routing of the power supply lines. On the other hand, having one capacitor to supply power in parallel to the multiple SRAM memory cells increases the requirement of the capacitance of the capacitor. For example, the capacitor 103 has a capacitance in a range of about 1500 nf to about 50000 nf, and the capacitor 103 is to supply power to the SRAM device 101 for a period of time in a range of about 1 second to about 360 seconds. In some embodiments, the multiple SRAM memory cells of the SRAM device 101, e.g., the SRAM memory cell 111, and the SRAM memory cell 113, has power supplied by the capacitor without a battery.

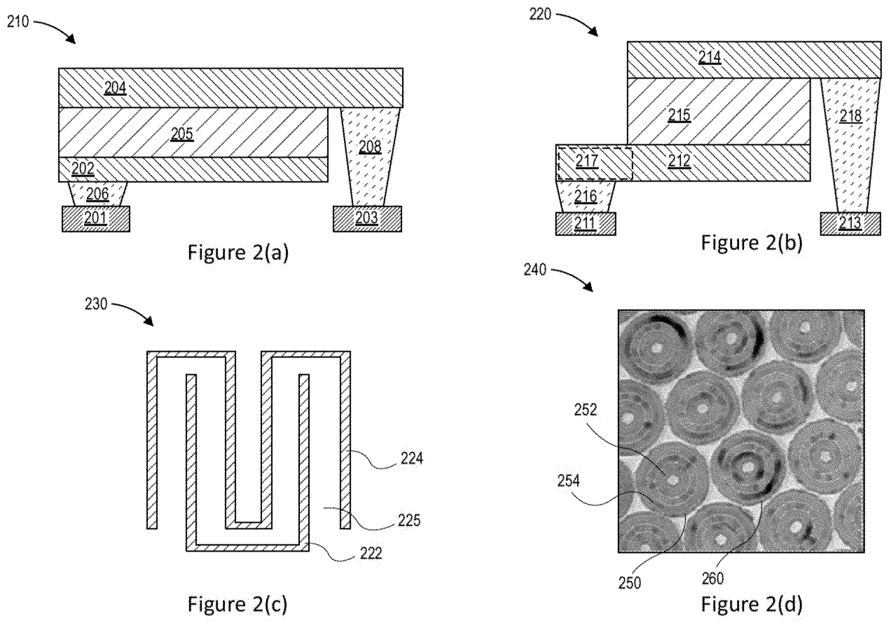

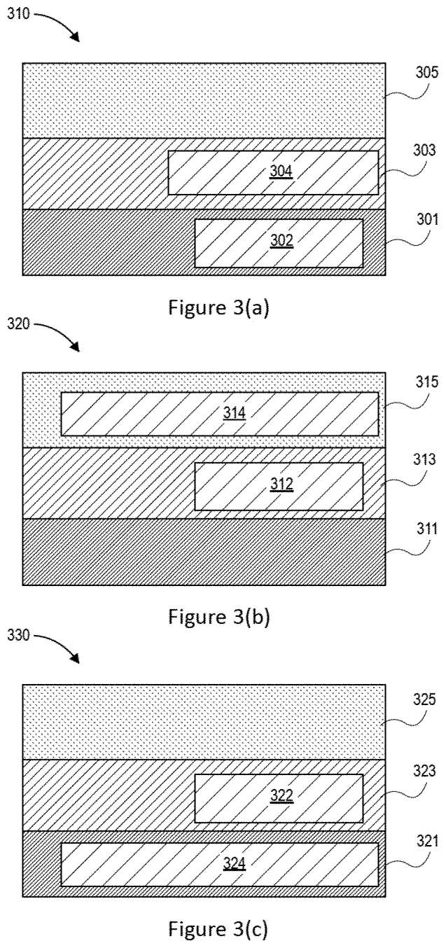

In embodiments, the capacitor 103 may be a planar capacitor, a metal-insulator-metal (MIM) capacitor, or a three dimensional capacitor. More details may be shown in FIGS. 2(a)-2(d) or FIGS. 3(a)-3(c). The capacitor 103 includes a first plate 102, a second plate 104, and a capacitor dielectric layer 105 between the first plate 102 and the second plate 104. The first plate 102 or the second plate 104 may be of a rectangular shape, a circular shape, a cubic shape, a cylindrical shape, or other shapes. The capacitor dielectric layer 105 may include includes ABO₃, PZT, BST, BZT, BCT, TiO2, HfO2, ZrO2, or BeO; and may have a thickness in a range of about 5 nm to about 10 nm.

FIGS. 2(a)-2(d) schematically illustrate various structures of a capacitor, e.g., a capacitor 210, a capacitor 220, a capacitor 230, a capacitor 250, and a capacitor 260, that can supply power in parallel to multiple SRAM memory cells of a SRAM device, in accordance with some embodiments. The capacitor 210, the capacitor 220, the capacitor 230, the capacitor 250, and the capacitor 260 may be an example of the capacitor 103 in FIG. 1.

In embodiments, as shown in FIG. 2(a), the capacitor 210 is a planar capacitor including a first plate 202, a second plate 204, and a capacitor dielectric layer 205 between the first plate 202 and the second plate 204. The first plate 202 and the second plate 204 may be a metal contact in a metal layer of a semiconductor device. Furthermore, the capacitor 210 may be coupled to a SRAM device by vias and other metal interconnects. For example, the first plate 202 is coupled to a via 206 and a metal contact 201, and the second plate 204 is coupled to a via 208 and a metal contact 203. As shown in FIG. 2(a), the first plate 202 and the second plate 204 may be substantially parallel to each other, and the capacitor dielectric layer 205 covers the entire surface of the first plate 202.

In embodiments, as shown in FIG. 2(b), the capacitor 220 is a planar capacitor including a first plate 212, a second plate 214, and a capacitor dielectric layer 215 between the first plate 212 and the second plate 214. The first plate 212 and the second plate 214 may be a metal contact in a metal layer of a semiconductor device. Furthermore, the capacitor 220 may be coupled to a SRAM device by vias and other metal interconnects. For example, the first plate 212 is coupled to a via 216 and a metal contact 211, and the second plate 214 is coupled to a via 218 and a metal contact 213. As shown in FIG. 2(a), the first plate 202 and the second plate 204 may be substantially parallel to each other. The capacitor dielectric layer 215 covers a part of the surface of the first plate 212, the first plate 212 has a part, e.g., a part 217, not covered by the capacitor dielectric layer 215.

In embodiments, as shown in FIG. 2(c), the capacitor 230 is a MIM capacitor including a first plate 222, a second plate 224, and a capacitor dielectric layer 225 between the first plate 222 and the second plate 224. The first plate 222 and the second plate 224 may be a U-shaped, and may be through multiple metal layers in a semiconductor device.

In embodiments, as shown in FIG. 2(d), a semiconductor device 240 may include multiple capacitors, e.g., the a capacitor 250, and the capacitor 260, coupled in series to supply power in parallel to multiple SRAM memory cells of the SRAM device. For example, the capacitor 250, and the capacitor 260 may be used as the capacitor 101 to supply power to the multiple SRAM memory cells of the SRAM device 101. The capacitor 250 and the capacitor 260 may be of three dimensional cylindrical shape. For example, the capacitor 250 is of a pillar shape with an aspect ratio of about 100×1. The capacitor 250 includes a first plate 252, a second plate 254, and a capacitor dielectric layer between the first plate 252 and the second plate 254.

FIGS. 3(a)-3(c) schematically illustrate semiconductor devices including a capacitor to supply power in parallel to multiple SRAM memory cells of a SRAM device, in accordance with some embodiments. For example, as shown in FIG. 3(a), a semiconductor device 310 includes a capacitor 304 to supply power in parallel to multiple SRAM memory cells of a SRAM device 302. As shown in FIG. 3(b), a semiconductor device 320 includes a capacitor 314 to supply power in parallel to multiple SRAM memory cells of a SRAM device 312. As shown in FIG. 3(c), a semiconductor device 330 includes a capacitor 324 to supply power in parallel to multiple SRAM memory cells of a SRAM device 322. In embodiments, the capacitor 304, the capacitor 314, the capacitor 324, the SRAM device 302, the SRAM device 312, and the SRAM device 322, may be examples of the capacitor 103 and the SRAM device 101 as shown in FIG. 1.

In embodiments, as shown in FIG. 3(a), the semiconductor device 310 includes the capacitor 304 to supply power in parallel to multiple SRAM memory cells of the SRAM device 302. The semiconductor device 310 includes a layer 301, which is a Front-end-of-line (FEOL) layer above a substrate, and further includes a layer 303 above the layer 301, and a layer 305 above the layer 303. The layer 303 is a back end of line (BEOL) layer, and the layer 305 is a far backend layer.

In embodiments, the manufacturing process for integrated circuits (IC) or devices may include many steps and operations performed on a device wafer. FEOL, or simply front end, semiconductor processing and structures may refer to a first portion of integrated circuit fabrication where individual devices (e.g., transistors, capacitors, resistors, etc.) are patterned in a semiconductor substrate or layer at the front side of the device wafer. FEOL generally covers everything up to (but not including) the deposition of metal interconnect layers. Following the last FEOL operation, the result is typically a wafer with isolated transistors (e.g., without any wires). BEOL, or simply back end, semiconductor processing and structures may refer to a second portion of IC fabrication where the individual devices (e.g., transistors, capacitors, resistors, etc.) are interconnected with wiring on the wafer, e.g., the metallization layer or layers. BEOL includes a metal interconnect, e.g., metal contacts, vias, dielectrics layers, metal levels, and bonding sites for chip-to-package connections. For modern IC processes, more than 10 metal layers may be added in the BEOL. A far backend layer may be formed on the BEOL layer. A far backend layer may refer to the portion of the semiconductor processing that creates the metal layer (e.g., the under-bump-metal or redistribution layer) and associated interconnect structures forming the connection between on-chip and off-chip wiring.

As shown in FIG. 3(a), the capacitor 304 is located in the layer 303, which is the BEOL layer, and the SRAM device 302 is located in the layer 301, which is the FEOL layer, both below the layer 305, which is the far backend layer. The capacitor 304 is above the SRAM device 302 with respect to a substrate of the semiconductor device 310.

As shown in FIG. 3(b), the capacitor 314 is located in the layer 315, which is the far backend layer, and the SRAM device 302 is located in the layer 313, which is the BEOL layer, both above the layer 311, which is the FEOL layer. The capacitor 314 is above the SRAM device 312 with respect to a substrate of the semiconductor device 320.

As shown in FIG. 3(c), the capacitor 324 is located in the layer 321, which is the FEOL layer, and the SRAM device 322 is located in the layer 323, which is the BEOL layer, both below the layer 325, which is the far backend layer. The capacitor 324 is below the SRAM device 322 with respect to a substrate of the semiconductor device 330.

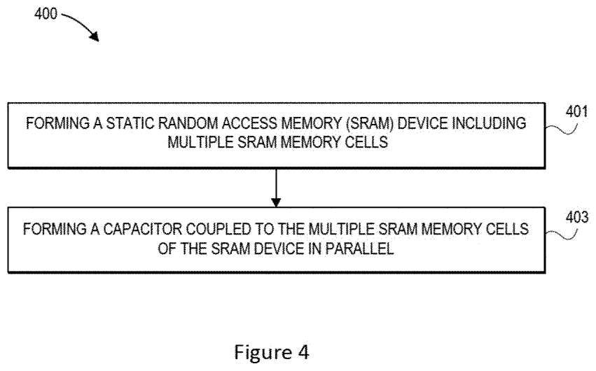

FIG. 4 schematically illustrates a process 400 for forming a semiconductor device including a capacitor to supply power in parallel to multiple SRAM memory cells of a SRAM device, in accordance with some embodiments. In embodiments, the process 400 may be applied to form the capacitor 103 to supply power in parallel to multiple SRAM memory cells of the SRAM device 101 in FIG. 1, form the capacitor 304 to supply power in parallel to multiple SRAM memory cells of the SRAM device 302 in FIG. 3(a), form the capacitor 314 to supply power in parallel to multiple SRAM memory cells of the SRAM device 312 in FIG. 3(b), or form the capacitor 324 to supply power in parallel to multiple SRAM memory cells of the SRAM device 322 in FIG. 3(c).

At block 401, the process 400 may include forming a SRAM device including multiple SRAM memory cells. For example, as shown in FIG. 1, the process 400 may include forming the SRAM device 101 including multiple SRAM memory cells, e.g., the SRAM memory cell 111 and the SRAM memory cell 113.

At block 403, the process 400 may include forming a capacitor coupled to the multiple SRAM memory cells of the SRAM device in parallel. For example, as shown in FIG. 1, the process 400 may include forming the capacitor 103 coupled to the multiple SRAM memory cells, e.g., the SRAM memory cell 111 and the SRAM memory cell 113, of the SRAM device 101 in parallel. The capacitor 103 includes the first plate 102, the second plate 104, and the capacitor dielectric layer 105 between the first plate 102 and the second plate 104.

In addition, the process 400 may include further operations, such as forming additional capacitors of three dimensional cylindrical shape coupled in series to supply power in parallel to the multiple SRAM memory cells of the SRAM device, forming transistors at the FEOL, forming metal contacts in the BEOL, and packing operations.

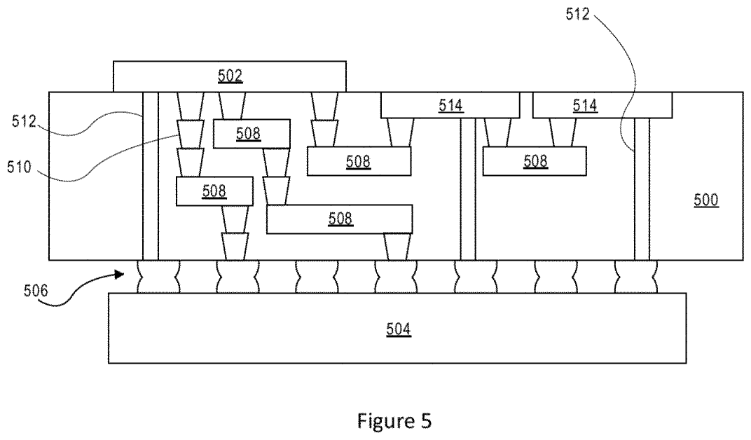

FIG. 5 illustrates an interposer 500 that includes one or more embodiments of the disclosure. The interposer 500 is an intervening substrate used to bridge a first substrate 502 to a second substrate 504. The first substrate 502 may be, for instance, a substrate support the capacitor 103 and the SRAM device 101 in FIG. 1, the capacitor 304 and the SRAM device 302 in FIG. 3(a), the capacitor 314 and the SRAM device 312 in FIG. 3(b), or the capacitor 324 and the SRAM device 322 in FIG. 3(c), or a capacitor and a SRAM device formed by the process 400 shown in FIG. 4. The second substrate 504 may be, for instance, a memory module, a computer motherboard, or another integrated circuit die. Generally, the purpose of an interposer 500 is to spread a connection to a wider pitch or to reroute a connection to a different connection. For example, an interposer 500 may couple an integrated circuit die to a ball grid array (BGA) 506 that can subsequently be coupled to the second substrate 504. In some embodiments, the first and second substrates 502/504 are attached to opposing sides of the interposer 500. In other embodiments, the first and second substrates 502/504 are attached to the same side of the interposer 500. And in further embodiments, three or more substrates are interconnected by way of the interposer 500.

The interposer 500 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 508 and vias 510, including but not limited to through-silicon vias (TSVs) 512. The interposer 500 may further include embedded devices 514, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 500.

In accordance with embodiments of the disclosure, apparatuses or processes disclosed herein may be used in the fabrication of interposer 500.

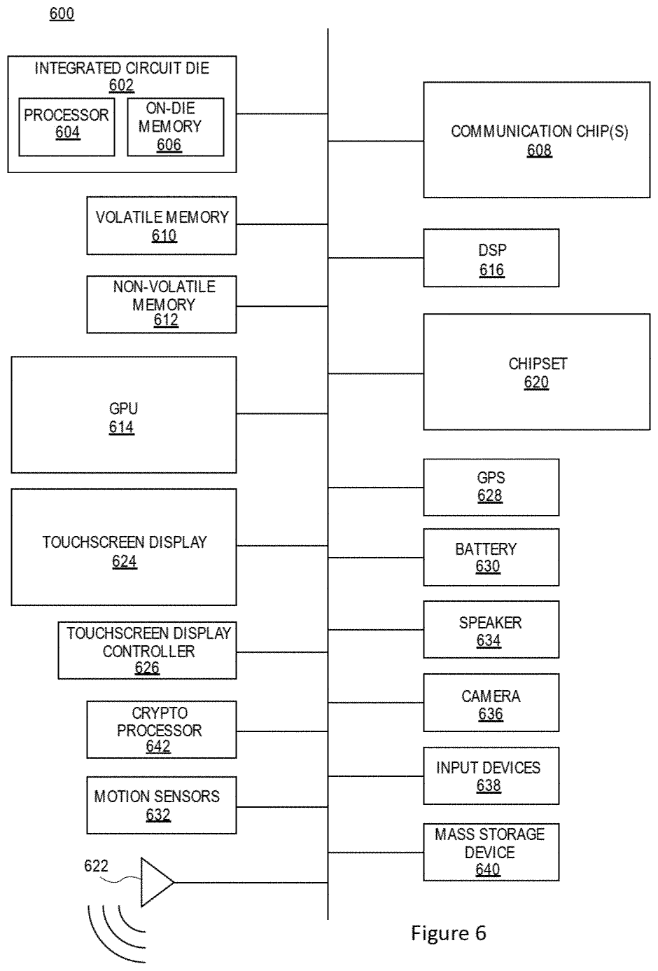

FIG. 6 illustrates a computing device 600 in accordance with one embodiment of the disclosure. The computing device 600 may include a number of components. In one embodiment, these components are attached to one or more motherboards. In an alternate embodiment, some or all of these components are fabricated onto a single system-on-a-chip (SoC) die, such as a SoC used for mobile devices. The components in the computing device 600 include, but are not limited to, an integrated circuit die 602 and at least one communications logic unit 608. In some implementations the communications logic unit 608 is fabricated within the integrated circuit die 602 while in other implementations the communications logic unit 608 is fabricated in a separate integrated circuit chip that may be bonded to a substrate or motherboard that is shared with or electronically coupled to the integrated circuit die 602. The integrated circuit die 602 may include a processor 604 as well as on-die memory 606, often used as cache memory, which can be provided by technologies such as embedded DRAM (eDRAM), or SRAM. In embodiments, the on-die memory 606 may be the SRAM device 101 in FIG. 1, the SRAM device 302 in FIG. 3(a), the SRAM device 312 in FIG. 3(b), the SRAM device 322 in FIG. 3(c), or a SRAM device formed by the process 400 shown in FIG. 4.

In embodiments, the computing device 600 may include a display or a touchscreen display 624, and a touchscreen display controller 626. A display or the touchscreen display 624 may include a FPD, an AMOLED display, a TFT LCD, a micro light-emitting diode (μLED) display, or others.

The computing device 600 may include other components that may or may not be physically and electrically coupled to the motherboard or fabricated within a SoC die. These other components include, but are not limited to, volatile memory 610 (e.g., dynamic random access memory (DRAM), non-volatile memory 612 (e.g., ROM or flash memory), a graphics processing unit 614 (GPU), a digital signal processor (DSP) 616, a crypto processor 642 (e.g., a specialized processor that executes cryptographic algorithms within hardware), a chipset 620, at least one antenna 622 (in some implementations two or more antenna may be used), a battery 630 or other power source, a power amplifier (not shown), a voltage regulator (not shown), a global positioning system (GPS) device 628, a compass, a motion coprocessor or sensors 632 (that may include an accelerometer, a gyroscope, and a compass), a microphone (not shown), a speaker 634, user input devices 638 (such as a keyboard, mouse, stylus, and touchpad), and a mass storage device 640 (such as hard disk drive, compact disk (CD), digital versatile disk (DVD), and so forth). The computing device 600 may incorporate further transmission, telecommunication, or radio functionality not already described herein. In some implementations, the computing device 600 includes a radio that is used to communicate over a distance by modulating and radiating electromagnetic waves in air or space. In further implementations, the computing device 600 includes a transmitter and a receiver (or a transceiver) that is used to communicate over a distance by modulating and radiating electromagnetic waves in air or space.

The communications logic unit 608 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communications logic unit 608 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Infrared (IR), Near Field Communication (NFC), Bluetooth, derivatives thereof, as well as any other wireless protocols that are designated as 3G, 4G, 5G, and beyond. The computing device 600 may include a plurality of communications logic units 608. For instance, a first communications logic unit 608 may be dedicated to shorter range wireless communications such as Wi-Fi, NFC, and Bluetooth and a second communications logic unit 608 may be dedicated to longer range wireless communications such as GPS, EDGE, GPRS, CDMA, WiMAX, LTE, Ev-DO, and others.

The processor 604 of the computing device 600 includes one or more devices, such as transistors. The term “processor” may refer to any device or portion of a device that processes electronic data from registers and/or memory to transform that electronic data into other electronic data that may be stored in registers and/or memory. The communications logic unit 608 may also include one or more devices, such as transistors.

In various embodiments, the computing device 600 may be a laptop computer, a netbook computer, a notebook computer, an ultrabook computer, a smartphone, a dumbphone, a tablet, a tablet/laptop hybrid, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

### Some Non-Limiting Examples are Provided Below

Example 1 may include a semiconductor device, comprising: a static random access memory (SRAM) device including multiple SRAM memory cells; and a capacitor coupled to the SRAM device, wherein the capacitor includes a first plate, a second plate, and a capacitor dielectric layer between the first plate and the second plate, the capacitor is to supply power in parallel to the multiple SRAM memory cells of the SRAM device for a period of time.

Example 2 may include the semiconductor device of example 1, wherein the capacitor is a planar capacitor, a metal-insulator-metal (MIM) capacitor, or a three dimensional capacitor, and the first plate or the second plate is of a rectangular shape, a circular shape, a cubic shape, or a cylindrical shape.

Example 3 may include the semiconductor device of examples 1-2, wherein the capacitor dielectric layer includes ABO₃, PZT, BST, BZT, BCT, TiO2, HfO2, ZrO2, or BeO.

Example 4 may include the semiconductor device of examples 1-3, wherein the capacitor is of a three dimensional cylindrical shape, and the semiconductor device further include additional capacitors of three dimensional cylindrical shape coupled in series to supply power in parallel to the multiple SRAM memory cells of the SRAM device.

Example 5 may include the semiconductor device of examples 1-3, wherein the capacitor is of a pillar shape with an aspect ratio of about 100×1.

Example 6 may include the semiconductor device of examples 1-5, wherein the multiple SRAM memory cells of the SRAM device has power supplied by the capacitor without a battery.

Example 7 may include the semiconductor device of examples 1-6, wherein the multiple SRAM memory cells includes a SRAM memory cell with 4 transistors, a SRAM memory cell with 6 transistors, or a SRAM memory cell with 8 transistors.

Example 8 may include the semiconductor device of examples 1-7, wherein the capacitor is located in a frontend level of the semiconductor device, a backend level of the semiconductor device, or a far backend level of the semiconductor device.

Example 9 may include the semiconductor device of examples 1-8, wherein the capacitor is above the SRAM device with respect to a substrate of the semiconductor device.

Example 10 may include the semiconductor device of examples 1-9, wherein the period of time is in a range of about 1 second to about 360 seconds.

Example 11 may include the semiconductor device of examples 1-10, wherein the SRAM device has a size in a range of about 4 kb to 32 Mb.

Example 12 may include the semiconductor device of examples 1-11, wherein the capacitor has a capacitance in a range of about 1500 nf to about 50000 nf.

Example 13 may include the semiconductor device of examples 1-12, wherein the capacitor dielectric layer has a thickness in a range of about 5 nm to about 10 nm.

Example 14 may include the semiconductor device of examples 1-13, further comprising: a processor, wherein the SRAM device is located in a cache of the processor.

Example 15 may include a method for forming a semiconductor device, the method comprising: forming a static random access memory (SRAM) device including multiple SRAM memory cells; and forming a capacitor coupled to the multiple SRAM memory cells of the SRAM device in parallel, wherein the capacitor includes a first plate, a second plate, and a capacitor dielectric layer between the first plate and the second plate, the capacitor is to supply power in parallel to the multiple SRAM memory cells of the SRAM device for a period of time.

Example 16 may include the method of example 15, wherein the capacitor is a planar capacitor, a metal-insulator-metal (MIM) capacitor, or a three dimensional capacitor, and the first plate or the second plate is of a rectangular shape, a circular shape, a cubic shape, or a cylindrical shape.

Example 17 may include the method of examples 15-16, wherein the capacitor dielectric layer includes ABO₃, PZT, BST, BZT, BCT, TiO2, HfO2, ZrO2, or BeO.

Example 18 may include the method of examples 15-17, wherein the capacitor is of a three dimensional cylindrical shape, and the method further includes: forming additional capacitors of three dimensional cylindrical shape coupled in series to supply power in parallel to the multiple SRAM memory cells of the SRAM device.

Example 19 may include the method of examples 15-18, wherein the capacitor is of a pillar shape with an aspect ratio of about 100×1.

Example 20 may include the method of examples 15-19, wherein the multiple SRAM memory cells of the SRAM device has power supplied by the capacitor without a battery.

Example 21 may include the method of examples 15-19, wherein the capacitor is located in a frontend level of the semiconductor device, a backend level of the semiconductor device, or a far backend level of the semiconductor device.

Example 22 may include a computing device, comprising: a print circuit board (PCB); a static random access memory (SRAM) device coupled to the PCB, wherein the SRAM device includes multiple SRAM memory cells; and a capacitor coupled to the SRAM device, wherein the capacitor includes a first plate, a second plate, and a capacitor dielectric layer between the first plate and the second plate, the capacitor is to supply power in parallel to the multiple SRAM memory cells of the SRAM device for a period of time.

Example 23 may include the computing device of example 22, the capacitor is of a three dimensional cylindrical shape, and the semiconductor device further include additional capacitors of three dimensional cylindrical shape coupled in series to supply power in parallel to the multiple SRAM memory cells of the SRAM device.

Example 24 may include the computing device of examples 22-23, wherein the capacitor is a planar capacitor, a metal-insulator-metal (MIM) capacitor, or a three dimensional capacitor, and the first plate or the second plate is of a rectangular shape, a circular shape, a cubic shape, or a cylindrical shape; and the capacitor dielectric layer includes ABO₃, PZT, BST, BZT, BCT, TiO2, HfO2, ZrO2, or BeO.

Example 25 may include the computing device of examples 22-24, wherein the computing device includes a device selected from the group consisting of a wearable device or a mobile computing device, the wearable device or the mobile computing device including one or more of an antenna, a touchscreen controller, a display, a battery, a processor, an audio codec, a video codec, a power amplifier, a global positioning system (GPS) device, a compass, a Geiger counter, an accelerometer, a gyroscope, a speaker, and a camera coupled with the memory device.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations, including what is described in the Abstract, is not intended to be exhaustive or to limit the embodiments of the present disclosure to the precise forms disclosed. While specific implementations and examples are described herein for illustrative purposes, various equivalent modifications are possible within the scope of the present disclosure, as those skilled in the relevant art will recognize.

These modifications may be made to embodiments of the present disclosure in light of the above detailed description. The terms used in the following claims should not be construed to limit various embodiments of the present disclosure to the specific implementations disclosed in the specification and the claims. Rather, the scope is to be determined entirely by the following claims, which are to be construed in accordance with established doctrines of claim interpretation.

What is claimed is:

1. A semiconductor device, comprising:
a static random access memory (SRAM) device including multiple SRAM memory cells; and
a capacitor coupled to the SRAM device, wherein the capacitor includes a first plate, a second plate, and a capacitor dielectric layer between the first plate and the second plate, the capacitor is to supply power in parallel to the multiple SRAM memory cells of the SRAM device for a period of time.

2. The semiconductor device of claim 1, wherein the capacitor is a planar capacitor, a metal-insulator-metal (MIM) capacitor, or a three dimensional capacitor, and the first plate or the second plate is of a rectangular shape, a circular shape, a cubic shape, or a cylindrical shape.

3. The semiconductor device of claim 1, wherein the capacitor dielectric layer includes ABO₃, PZT, BST, BZT, BCT, TiO2, HfO2, ZrO2, or BeO.

4. The semiconductor device of claim 1, wherein the capacitor is of a three dimensional cylindrical shape, and the semiconductor device further include additional capacitors of three dimensional cylindrical shape coupled in series to supply power in parallel to the multiple SRAM memory cells of the SRAM device.

5. The semiconductor device of claim 1, wherein the capacitor is of a pillar shape with an aspect ratio of about 100×1.

6. The semiconductor device of claim 1, wherein the multiple SRAM memory cells of the SRAM device has power supplied by the capacitor without a battery.

7. The semiconductor device of claim 1, wherein the multiple SRAM memory cells includes a SRAM memory cell with 4 transistors, a SRAM memory cell with 6 transistors, or a SRAM memory cell with 8 transistors.

8. The semiconductor device of claim 1, wherein the capacitor is located in a frontend level of the semiconductor device, a backend level of the semiconductor device, or a far backend level of the semiconductor device.

9. The semiconductor device of claim 1, wherein the capacitor is above the SRAM device with respect to a substrate of the semiconductor device.

10. The semiconductor device of claim 1, wherein the period of time is in a range of about 1 second to about 360 seconds.

11. The semiconductor device of claim 1, wherein the SRAM device has a size in a range of about 4 kb to 32 Mb.

12. The semiconductor device of claim 1, wherein the capacitor has a capacitance in a range of about 1500 nf to about 50000 nf.

13. The semiconductor device of claim 1, wherein the capacitor dielectric layer has a thickness in a range of about 5 nm to about 10 nm.

14. The semiconductor device of claim 1, further comprising:
a processor, wherein the SRAM device is located in a cache of the processor.

15. A method for forming a semiconductor device, the method comprising:
forming a static random access memory (SRAM) device including multiple SRAM memory cells; and
forming a capacitor coupled to the multiple SRAM memory cells of the SRAM device in parallel, wherein the capacitor includes a first plate, a second plate, and a capacitor dielectric layer between the first plate and the second plate, the capacitor is to supply power in parallel to the multiple SRAM memory cells of the SRAM device for a period of time.

16. The method of claim 15, wherein the capacitor is a planar capacitor, a metal-insulator-metal (MIM) capacitor, or a three dimensional capacitor, and the first plate or the second plate is of a rectangular shape, a circular shape, a cubic shape, or a cylindrical shape.

17. The method of claim 15, wherein the capacitor dielectric layer includes ABO₃, PZT, BST, BZT, BCT, TiO2, HfO2, ZrO2, or BeO.

18. The method of claim 15, wherein the capacitor is of a three dimensional cylindrical shape, and the method further includes:
forming additional capacitors of three dimensional cylindrical shape coupled in series to supply power in parallel to the multiple SRAM memory cells of the SRAM device.

19. The method of claim 15, wherein the capacitor is of a pillar shape with an aspect ratio of about 100×1.

20. The method of claim 15, wherein the multiple SRAM memory cells of the SRAM device has power supplied by the capacitor without a battery.

21. The method of claim 15, wherein the capacitor is located in a frontend level of the semiconductor device, a backend level of the semiconductor device, or a far backend level of the semiconductor device.

22. A computing device, comprising:
a print circuit board (PCB);
a static random access memory (SRAM) device coupled to the PCB, wherein the SRAM device includes multiple SRAM memory cells; and
a capacitor coupled to the SRAM device, wherein the capacitor includes a first plate, a second plate, and a capacitor dielectric layer between the first plate and the second plate, the capacitor is to supply power in parallel to the multiple SRAM memory cells of the SRAM device for a period of time.

23. The computing device of claim 22, the capacitor is of a three dimensional cylindrical shape, and the semiconductor device further include additional capacitors of three dimensional cylindrical shape coupled in series to supply power in parallel to the multiple SRAM memory cells of the SRAM device.

24. The computing device of claim 22, wherein the capacitor is a planar capacitor, a metal-insulator-metal (MIM) capacitor, or a three dimensional capacitor, and the first plate or the second plate is of a rectangular shape, a circular shape, a cubic shape, or a cylindrical shape; and
the capacitor dielectric layer includes ABO₃, PZT, BST, BZT, BCT, TiO2, HfO2, ZrO2, or BeO.

25. The computing device of claim 22, wherein the computing device includes a device selected from the group consisting of a wearable device or a mobile computing device, the wearable device or the mobile computing device including one or more of an antenna, a touchscreen controller, a display, a battery, a processor, an audio codec, a video codec, a power amplifier, a global positioning system (GPS) device, a compass, a Geiger counter, an accelerometer, a gyroscope, a speaker, and a camera coupled with the memory device.
